(19) United States
(12) Patent Application Publication
(10) Pub. No.: US 2024/0400379 A1
(43) Pub. Date: Dec. 5, 2024

(54) Device and Method for Adapting Measuring Range and Sensitivity of Micromechanical Sensors

(71) Applicant: Ruhr-Universität Bochum, Bochum (DE)

(72) Inventors: Philip Schmitt, Bochum (DE); Martin Hoffmann, Bochum (DE)

(21) Appl. No.: 18/680,386

(22) Filed: May 31, 2024

(30) Foreign Application Priority Data
Jun. 1, 2023 (DE) 10 2023 114 462.6

(51) Int. Cl. B81B 3/00; G01B 7/16

(52) U.S. Cl. CPC B81B 3/0086; G01B 7/22; B81B 2201/0235; B81B 2201/0278; B81B 2201/033; B81B 2203/0163; B81B 2203/04

(57) ABSTRACT

A measuring system based on micromechanical elements, including an energy converter which is configured to convert a physical signal into a displacement of the energy converter, a force generator which is configured to convert the displacement from the energy converter into a force on a movably mounted slider, and an electrostatic actuator which is mechanically connected to the slider and/or an electrostatic anti-spring which is mechanically connected to the slider, and an electromechanical signal converter which converts a displacement of the slider into an electrical signal, the electrostatic actuator being configured to convert the displacement from the energy converter into a force on a movably mounted slider, which is mechanically connected to the slider, and an electromechanical signal converter which converts a displacement of the slider into an electrical signal, wherein the electrostatic actuator is configured to set an offset compensation of the measuring system via a control voltage and/or the electrostatic anti-spring is configured to set a sensitivity of the measuring system via a control voltage.

The present application is based upon and claims the right of priority to DE Patent Application No. 10 2023 114 462.6, filed Jun. 1, 2023, the disclosure of which is hereby incorporated by reference herein in its entirety for all purposes.

The invention relates to a sensor system and an associated method for adjusting the measuring range and increasing the sensitivity of a micromechanical sensor. In particular, the device can be integrated into micromechanical strain sensors, acceleration sensors or temperature sensors. In particular, the invention makes it possible to use a micromechanical sensor element to cover a wide measuring range and simultaneously increase the measuring resolution step by step.

Micromechanical-electrical sensors, also known as MEMS (Micro Electro-Mechanical System) sensors, typically involve a chip-based technology in which the sensors usually consist of a suspended mass between a pair of capacitive plates. When the sensor is moved or tilted, for example, a difference in electrical potential is generated by this suspended mass. This difference is then measured as a change in capacitance.

Sensors of all kinds have a characteristic curve which approximates their essential (measurement) characteristic, i.e. represents the response function to a specific input or measured variable. This characteristic curve, generally represented by a linear equation, e.g. in the form of y (x)=a*x+b, is not always ideal for the measurement to be carried out. The sensitivity corresponds to the parameter for the slope and the offset corresponds to the y-axis section with the parameter b. An adaptation of the characteristic curve to a current measurement range generally enables an increase in measurement accuracy.

The sensitivity and measuring range of strain or acceleration sensors, for example, are usually set electronically by the signal processing or evaluation electronics, for example by increasing the resolution of an analog-to-digital converter or by changing the amplification factor on an instrumentation amplifier. The sensitivity is therefore only adjusted on the signal that has already been recorded and converted. To increase the detectable measuring range, several sensor elements with different, in particular neighboring measuring ranges have been used up to now or the sensor element has been physically replaced.

EP 3 822 577 A1 describes a MEMS sensor that is used to measure mechanical strain via two connecting elements, the displacement of which is amplified by a mechanical amplifier and converted into an electrical variable by an electromechanical converter.

It is therefore the objective technical problem of the invention to provide a sensor or measuring system with which the aforementioned disadvantages are avoided and, in particular, the measuring accuracy or the measuring range and/or the sensitivity of a MEMS sensor are improved.

This task is solved by a device according to claim 1 and a method according to claim 13. Preferred further embodiments can be found in the subclaims.

The measuring principle implemented in the context of the invention aims to adapt the measuring range and/or the sensitivity directly during the detection of the signal with the hardware and thus by the sensor element itself, i.e. the sensor properties of the detecting element itself are changed.

According to the invention, a measuring system based on micromechanical elements is provided, comprising an energy converter which is configured to convert a physical signal into a displacement of the energy converter, a force generator which is configured to convert the displacement from the energy converter into a force on a movably mounted slider, and an electrostatic anti-spring, which is mechanically connected to the slider, and an electromechanical signal converter, which converts a displacement of the slider into an electrical signal, wherein the electrostatic anti-spring is configured to adjust a sensitivity of the measuring system via a control voltage.

The control voltage makes it possible to shift the measuring system characteristic and thus adapt it to a particular application in order to increase the measuring range and/or the accuracy and/or the sensitivity of a MEMS-based measuring system.

A slider refers in particular to a mechanical element that is movably suspended or mounted and can transmit forces or movements.

The advantages of the invention can be summarized as follows: The sensitivity of a micromechanical sensor can consequently be adjusted by applying a voltage. The measuring range can also be shifted by applying a voltage.

Special advantages for the implementation of a strain sensor are the strain measurement via a single chip and no complex electrical amplifier circuit is required. The invention also enables a significant reduction in the additional evaluation electronics required.

Also, no parasitic electrical effects such as electrical noise or high cross-sensitivity with regard to temperature changes are possible, since a purely mechanical principle without resistance is present. The sensors or measuring systems according to the invention also enable wafer-level production of the sensor chips and consequently mass production and thus low-cost production. There is also no need for piece calibration or trimming as in the case of trimming the basic resistance in a strain gauge.

In particular, the invention comprises a measuring system comprising an energy transducer such as a seismic mass, a force generator, a mechanical amplification mechanism, an electrostatic anti-spring and optionally an actuator for offset compensation as well as an electromechanical transducer. The energy converter is designed to convert a physical signal (e.g. pressure, strain, acceleration, temperature, etc.) into a displacement. The force generator, for example in the form of a spring, finally converts this displacement into a force. Counterforces from the electrostatic anti-spring, the actuator for offset compensation and the counterforces of other optional guide springs reduce or increase the deflection at the force generator. The resulting displacement of the force generator is typically amplified by a mechanical amplifier and finally transferred indirectly or directly to the electromechanical signal converter, which converts the displacement into an electrically evaluable signal, for example into a change in capacitance. The exact arrangement of the components can vary.

In a preferred embodiment, the electrostatic anti-spring is bidirectional and/or has varying electrode distances. Varying electrode distances allow the sensitivity of the entire measuring system to be changed, in particular by adjusting the control voltage. Bidirectional means in particular that the properties of the anti-spring are almost equivalent for both directions of movement or translation.

In a further preferred embodiment, the electrostatic anti-spring is designed as a symmetrical electrostatic comb drive with pairs of curved and possibly additional parallel plate electrodes. In particular, the combination of curved and parallel plate electrodes allows an advantageous adjustment of the sensitivity of the measuring system via the control voltage.

In a preferred realization of the measuring system, the slider is connected to an electrostatic actuator, whereby the electrostatic actuator is configured to adjust an offset compensation of the measuring system via a control voltage. The control voltage on the actuator thus enables an additional shift of the measuring system characteristic and thus a further possibility for adaptation to a respective application, in particular for a change in the measuring range and/or the accuracy and/or the sensitivity of a MEMS-based measuring system.

In a particularly preferred embodiment, the electrostatic actuator is designed as a symmetrical electrostatic comb drive with pairs of parallel plate electrodes. The characteristic of a comb drive with pairs of parallel plate electrodes allows a relatively simple adjustment or correction of a constant offset for the measuring system by means of a control voltage to be applied.

Preferably, the slider is connected to a micromechanical amplifier. The micromechanical amplifier can increase the amplitude of a translation or displacement, in particular by connecting levers in series. In particular, the micromechanical amplifier converts a translatory movement on the input side into an amplitude-enhanced translatory displacement on the output side by means of a series connection of levers.

In a particular embodiment, the slider has a return mechanism. This can be realized electromechanically in particular, but also purely mechanically, for example via spring elements.

In particular, the slider is held by means of guide springs. This also enables a floating and/or movable suspension of the slider.

Preferably, the electromechanical signal converter is based on a change in capacitance, as is the case with comb-type MEMS structures in particular, which are widely used.

The force generator can be implemented in a simple way using a mechanical spring. Electromechanical forms of realization are also conceivable for converting a physical signal into a translation and/or displacement in particular.

In a simple embodiment, the slider is a rigid mechanical element, for example a simple rod, to which further mechanical or MEMS elements can be coupled.

In a particularly preferred embodiment, the invention comprises a computer which is configured to perform the offset compensation and/or the sensitivity adjustment. For this purpose, the computer must record and evaluate signals from the measuring system and set the respective control voltage accordingly. This allows the settings to be made automatically in particular.

The invention also comprises a method for adapting the measuring range and/or increasing the sensitivity of a micromechanical measuring system, comprising the steps of: converting a physical signal into a displacement and/or translation by means of an energy converter, converting the displacement and/or translation from the energy converter into a force on a movably mounted slider by means of a force generator, and converting the displacement and/or translation of the slider into an electrical signal by means of an electromechanical signal converter, where the sensitivity of the measuring system is set via a control voltage of an electrostatic anti-spring, which is connected to the slider and/or the force generator.

The method can also provide for an offset compensation of the measuring system to be set via a control voltage of an electrostatic actuator, whereby the actuator is also connected to the slider and/or the force generator. The control voltage on the actuator then enables an additional shift of the measuring system characteristic and thus a further option for adapting to a particular application.

Preferably, the method comprises the steps of measuring using a micromechanical measuring system, performing offset compensation, increasing the sensitivity and repeating the measurement using the measuring system. In this way, an iterative improvement of the measurement accuracy or the measurement range and/or the sensitivity of a MEMS sensor or MEMS-based measurement system can be achieved.

The invention further comprises the use of the above-described micromechanical measuring system according to one of the preceding claims in a strain sensor or acceleration sensor or temperature sensor.

In the following, the invention is explained in further detail with reference to the drawings by means of a preferred embodiment example.

The drawings show

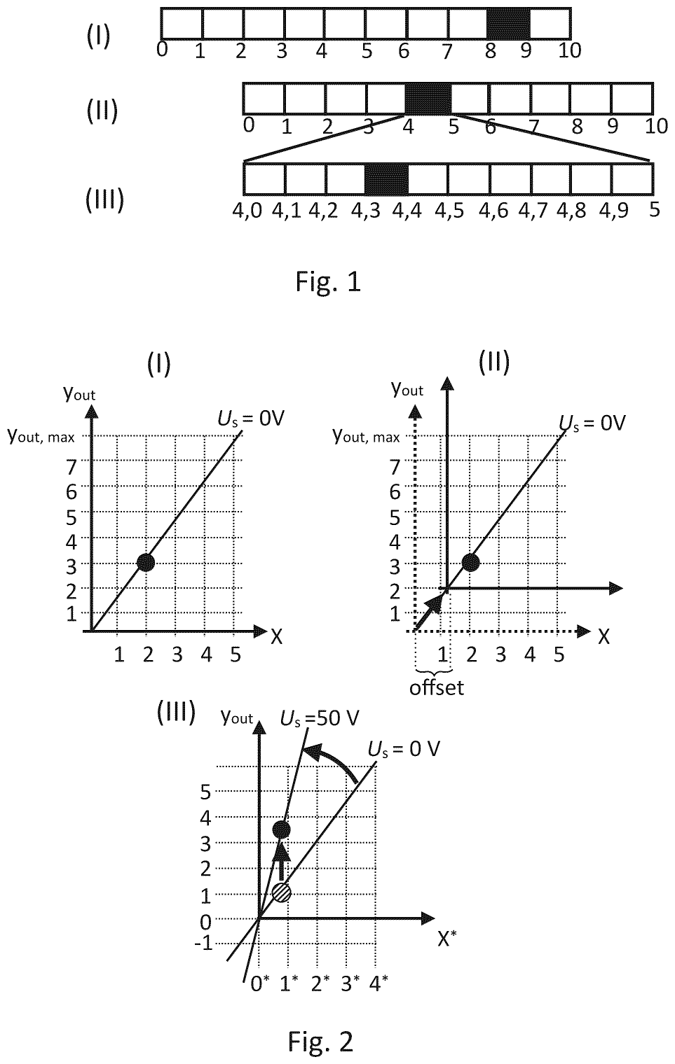

FIG. 1 a schematic basic principle for the iterative improvement of a measuring system according to a preferred embodiment of the invention,

FIG. 2 an illustration of the basic principle for the iterative improvement of a measuring system according to the invention using characteristic curves of the measuring system,

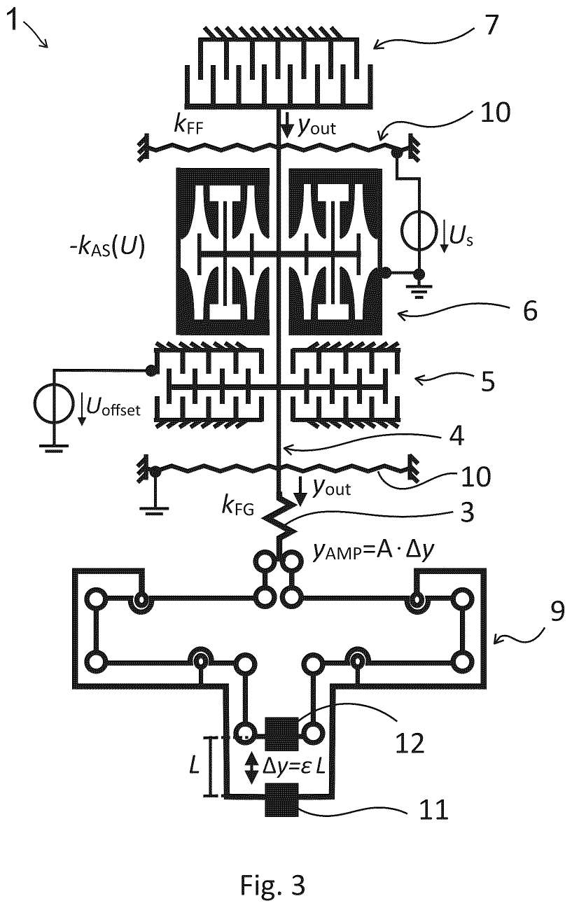

FIG. 3 a preferred embodiment of the invention with a strain measurement sensor,

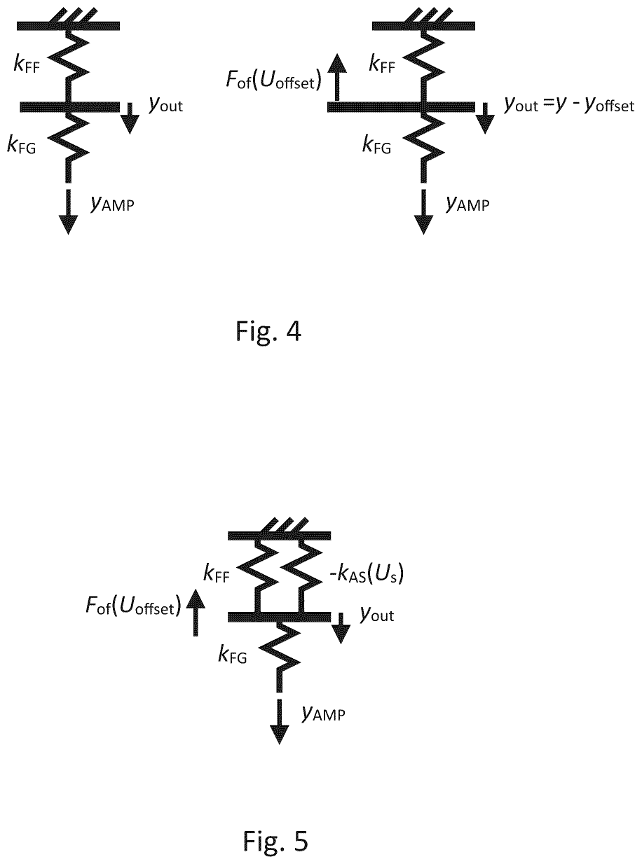

FIG. 4 Substitute diagrams to illustrate the forces involved,

FIG. 5 Further equivalent diagrams to illustrate the forces involved,

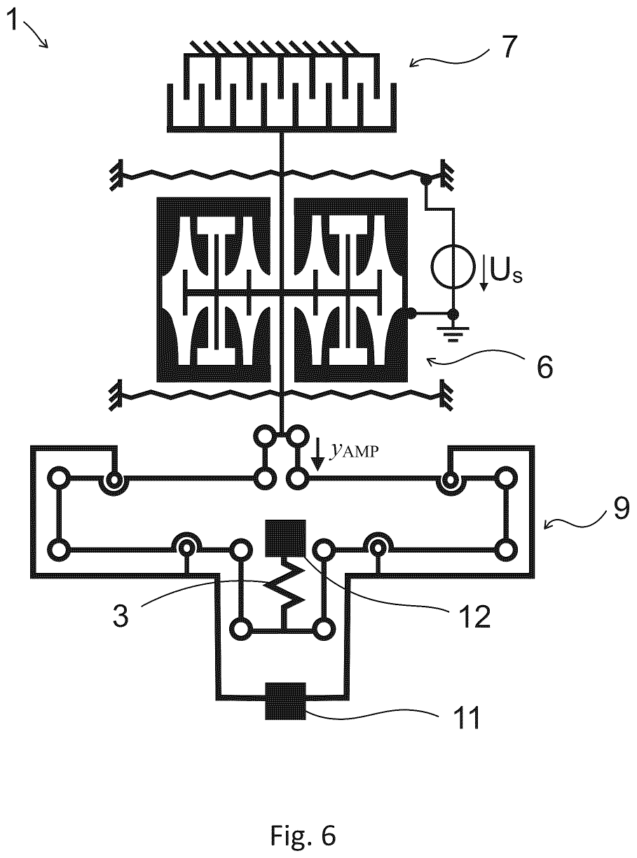

FIG. 6 a further embodiment of the sensor with a modified arrangement of the force generator,

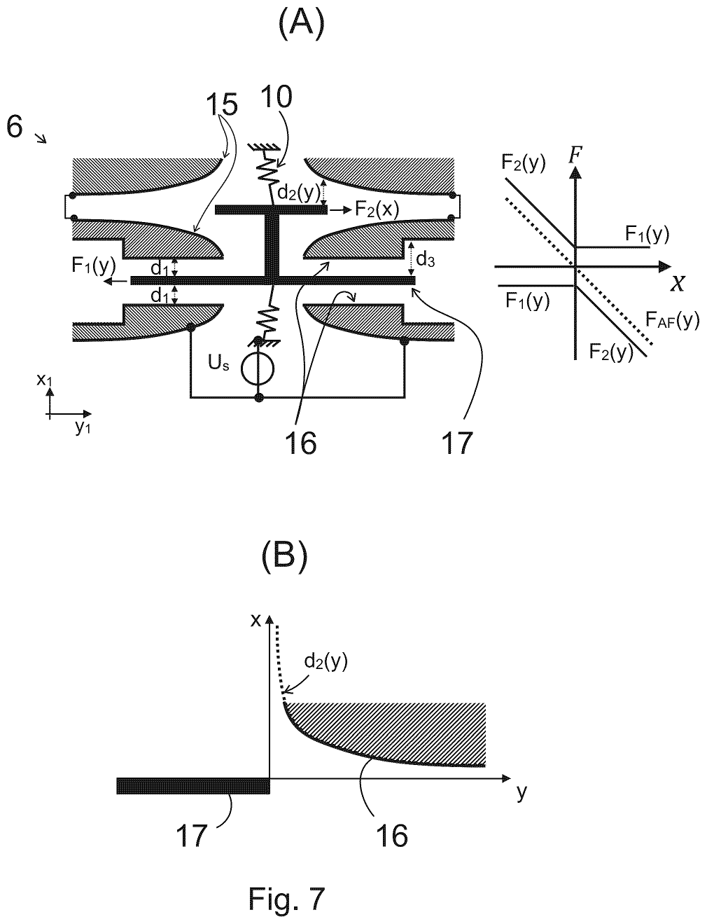

FIG. 7a preferred design example of an electrostatic anti-spring,

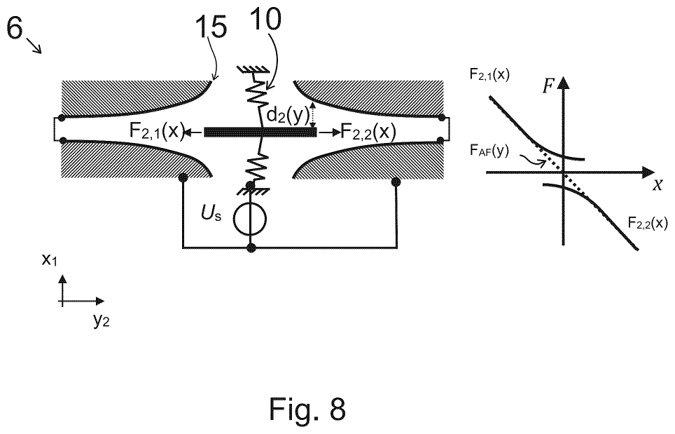

FIG. 8 another preferred embodiment of an electrostatic anti-spring and

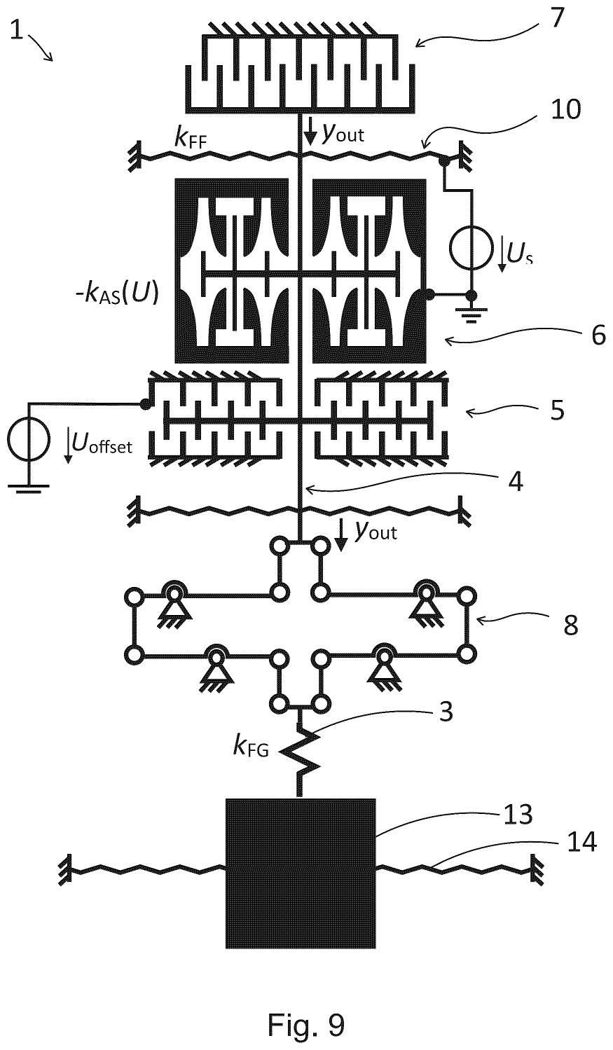

FIG. 9 a preferred embodiment of the invention with an acceleration sensor.

FIG. 1 first shows a basic approach for improving the measuring properties of a micromechanical measuring system 1. The measuring system 1 is initially designed or configured for a very wide measuring range. First, in step 1, a rough measurement is carried out with a wide measuring range. Then, in a second step, the measuring range is shifted so that the determined measured value is approximately in the middle of the new measuring range. In a third step, the sensitivity of the sensor is increased so that the measured value is resolved more accurately. The invention uses micromechanical components for shifting the measuring range (step 2) and increasing the sensitivity (step 3) so that the adjustments are made mechanically directly on the chip.

The basic concept of the device is explained below using the example of a strain sensor and is first illustrated in FIG. 2. In particular, this is a micromechanical strain sensor based on silicon. The strain sensor is mounted on a test object in the form of a chip, for example, and detects the strain on the object and converts it into an electrically evaluable signal, in particular into a change in capacitance. A key feature of the strain sensor is that the measuring range and/or the sensitivity can be influenced by applying at least one control voltage to a sensor according to the invention.

In a first step, the sensor first converts the measurement signal X-here in the form of a strain amplitude-into a displacement signal yₒᵤₜ. The displacement signal serves as the output variable of the sensor and can be coded via an encoder or converted into a change in capacitance via a capacitive transducer following data acquisition. For an unknown strain amplitude, it makes sense to cover as large a measuring range as possible with the sensor and thus initially determine the rough amplitude of the measured variable X (in this case strain). Here the measuring range is limited to a relatively high strain value of e.g. 5%. After the coarse strain amplitude has been determined in a first step (see FIG. 3, I), the offset is compensated in step 2 via a control voltage _{Uoffset} and thus the measuring range is shifted so that the measured value is now in the middle or approximately in the middle of the measuring range of the adapted sensor. As a result, measured values that were previously at the edge or even outside the originally defined measuring range can be recorded. In step 3, the sensitivity of the sensor is increased by applying a further control voltage U_{S} in order to implement a more precisely resolved measurement after the coarse measurement from step 1.

FIG. 3 shows a possible embodiment of the strain sensor. The device comprises a mechanical differential amplifier 9 with two contact points 11, 12, a force generator 3 in the form of a spring, an electrostatic actuator 5 for offset compensation, an electrostatic anti-spring 6 and an electromechanical signal converter 7. To detect strain, the sensor is connected to the test object via contact points-1- and -2-. The strain ε of the test object is thus coupled into the sensor via the contact points. Strain on the test object leads to a relative displacement of the two contact points in relation to each other. The mechanical differential amplifier 9 amplifies the relative displacement Δy by an amplification factor A and feeds the amplified displacement y_{AMP} into a force generator 3—in this case a spring. The amplified displacement is reduced by the counter forces of the guide springs 10, whereby the force generator 3 is compressed in the form of a spring and only passes on a reduced displacement yₒᵤₜ<y_{AMP} to the slider 4.

The equivalent circuit diagram in FIG. 4 (left) illustrates the acting springs and the resulting displacement. The displacement is a function of the spring constants k_{FG} (force generator (3)) and k_{FF} (guide springs 10):

$${y}_{out} = {y}_{AMP} \frac{{k}_{FG}}{{k}_{FG} + {k}_{FF}}$$

As the stiffness of the guide springs k_{FF} increases, the initial displacement yₒᵤₜ and thus the sensitivity is reduced.

If the electrostatic actuator 5 for offset compensation and the electrostatic anti-spring 6 are deactivated, i.e. if no voltage is applied to them, the displacement yₒᵤₜ is transferred to the electromechanical signal converter 7.

The signal converter 7 translates the displacement yₒᵤₜ into a change in an electrical state variable, usually a change in capacitance. The sensor now covers a wide measuring range with low sensitivity. If the measured value determined is now at the edge or slightly outside the measuring range, the electrostatic actuator 5 is activated.

Offset compensation activated by applying a voltage. The measuring range is shifted depending on the voltage U_{offset}. A shift of the measuring range corresponds to a mechanical shift of the slider 4. The actuator for offset compensation generates a constant force F_{of} as a function of the applied voltage, which is impressed on the force generator 3, whereby yₒᵤₜ is shifted by an offset, see FIG. 4 on the right. The following applies in simplified form:

$${y}_{out} = {y}_{AMP} \frac{{k}_{FG}}{{k}_{FG} + {k}_{FF}} \pm {F}_{of} ( {U}_{offset} ) ( {k}_{FG} + {k}_{FF} )$$

Depending on the direction of the force F_{of}, the displacement yₒᵤₜ is reduced or increased by the offset.

If the electrostatic anti-spring 6 is now also activated, the equivalent circuit diagram in FIG. 5 results.

The spring stiffness of the guide spring k_{FF} is now reduced by the negative spring stiffness −k_{AS} (Us) of the electrostatic anti-spring. This reduces the restoring counterforce of the guide springs and yₒᵤₜ achieves higher displacements depending on the impressed strain. Consequently, the sensitivity increases. The following then applies to the initial displacement in simplified form:

$${y}_{out} = {y}_{AMP} \frac{{k}_{FG}}{{k}_{FG} + {k}_{FF} - {k}_{AS} ( {U}_{S} )} \pm {F}_{of} ( {U}_{offset} ) ( {k}_{FG} + {k}_{FF} - {k}_{AS} ( {U}_{S} ) )$$

This allows the measuring range to be set via the offset voltage _{Uoffset and} the sensitivity of the measurement via U_{S}.

FIG. 6 shows a further embodiment of the strain sensor with a modified arrangement of the force generator 3 and without electrostatic actuator 5 for offset compensation. The force generator 3 is moved in front of the amplifier 9 in the effective sequence. The compensation of the stiffness by the anti-spring therefore takes place at the force generator before the displacement amplification. The lever amplifier amplifies the set stiffness at the anti-spring by the square of the amplification factor A and thus acts to a particularly high degree on the force generator 3.

A preferred embodiment of the electrostatic anti-spring is shown in FIG. 7A. The configuration comprises a symmetrical pairing of fixed curved electrodes 15 and fixed parallel electrodes 16 which are at a common first electrical potential (e.g. ground). Furthermore, movable inner electrodes 17 are required to which a second electrical potential (e.g. ground) is applied. Uₛ) is applied. The electrode distance d₂ (y) between the inner electrode 17 and the curved electrode 15 varies depending on the displacement y of the movable electrode. An electrostatic force is applied to the anti-spring as a function of the displacement y and the applied voltage Uₛ an electrostatic force F_{AF}(y, Uₛ) is generated. It is composed of the electrostatic force at the curved electrode F₂(y, Uₛ) and the force F₁(y, Uₛ) at the parallel electrode:

$${F}_{AF} ( y , {U}_{s} ) = {F}_{1} ( y , {U}_{s} ) - {F}_{2} ( y , {U}_{s} )$$

Both individual forces act in opposite directions. The parallel electrodes 16 are used to compensate for a possible offset of the electrostatic force F₂(y, Uₛ) within the anti-spring, as shown in the diagram in FIG. 7A on the right.

For the force F_{AF}(y, Uₛ) continues to apply:

$${F}_{AF} ( y , {U}_{s} ) = \frac{{ε}_{0} t}{{d}_{1}} {U}_{s}^{2} - \frac{{ε}_{0} t}{{d}_{2} ( y )} {U}_{s}^{2}$$

The parameter t here takes into account the thickness of the electrodes in the z-direction and ε₀ the permittivity. FIG. 7B shows a curved electrode 15 in detail. The electrodes 15 are designed in such a way that the following relationship applies for the electrode spacing d₂ (y) with the proportionality factor a and the displacement factor b:

$${d}_{2} ( y ) = \frac{a}{y + b}$$

For the constant distance d₁ between the inner electrode 17 and the parallel electrode 16:

$${d}_{1} = \frac{a}{b}$$

By deriving the force F_{AF}(y, Uₛ) according to the displacement y, the electrostatic stiffness of the anti-spring k_{AF}(Uₛ) as a function of the applied voltage Us:

$${k}_{AF} ( {U}_{s} ) = - \frac{{ε}_{0} t}{a} {U}_{s}^{2} .$$

FIG. 8 shows another preferred embodiment of the electrostatic anti-spring. Instead of additional parallel electrodes 16, the stray field at the edge of the curved electrodes 15 is used here to compensate for a possible offset of the electrostatic forces (see diagram in FIG. 8 on the right).

FIG. 9 shows another example of a sensor with adjustable sensitivity and measuring range. Acceleration is detected here instead of strain.

Instead of the contact points, the sensor now comprises a seismic mass 13 which is firmly suspended via springs 14 and which is connected to the input of a mechanical amplifier mechanism via the force generator 3.

Acceleration sensors are usually selected according to the expected acceleration so that the measuring range of the sensor covers the expected acceleration. However, as the size of the measuring range increases, the resolution of the sensor or measuring system 1 generally decreases.

If an acceleration of 100.4 g is expected, for example, a 6-bit sensor with a measuring range of 0 to 128 g is used. The expected measured value is therefore at the edge of the measuring range. The resolution of the sensor corresponds to 2 g/bit (=128 g/2⁶). This means that the measured value of 100.4 g is not fully resolved, but lies between the resolvable measured values of 100 g and 102 g In an equivalent version of the sensor with the device according to the invention, the measured value of 100 g±2 g is initially roughly recorded with the same measuring range of 0 to 128 g. However, the measuring range is now shifted so that the value 100 g lies in the middle of the measuring range. The measuring range is then between 36 g and 164 g. Now the sensitivity is increased by the anti-spring 6, e.g. tenfold, which also narrows the measuring range. The measuring range is now between 94 g and 106 g. The 6-bit resolution of the sensor now results in a resolution and increment of 0.2 g/bit (=12.8 g/2⁶). The measured value of 100.4 g can now be resolved with the same bit depth.

### LIST OF REFERENCE SYMBOLS

1 Measuring system
2 Energy converter
3 Force generator
4 Slider
5 Electrostatic actuator
6 Electrostatic anti-spring
7 Electromechanical signal converter
8 micromechanical amplifier
9 Mechanical differential amplifier
10 Guide spring
11 Contact point 1
12 Contact point 2
13 Seismic mass
14 Spring
15 Curved electrode of a preferred version of the anti-spring
16 Parallel electrode of a preferred version of the anti-spring
17 Movable electrode of a preferred version of the anti-spring

1. A measuring system based on micromechanical elements, comprising
an energy converter, which is configured to convert a physical signal into a displacement of the energy converter,
a force generator which is configured to convert the displacement of the energy converter into a force on a movably mounted slider, and
an electrostatic anti-spring, which is mechanically connected to the slider, and
an electromechanical signal converter which converts a displacement of the slider into an electrical signal,
wherein the electrostatic anti-spring is configured to adjust a sensitivity of the measuring system via a control voltage.

2. The measuring system according to claim 1, wherein the electrostatic anti-spring is bidirectional and/or has varying electrode spacings.

3. The measuring system according to claim 1, wherein the electrostatic anti-spring is configured as a symmetrical electrostatic comb drive with pairs of curved and parallel plate electrodes.

4. The measuring system according to claim 1, wherein the slider is connected to an electrostatic actuator, wherein the electrostatic actuator is configured to adjust an offset compensation of the measuring system via a control voltage.

5. The measuring system according to claim 4, wherein the electrostatic actuator is configured as a symmetrical electrostatic comb drive with pairs of parallel plate electrodes.

6. The measuring system according to claim 1, wherein the slider is connected to a micromechanical amplifier.

7. The measuring system according to claim 6, wherein the micromechanical amplifier converts an input-side translatory movement into an amplitude-amplified translatory displacement on the output side by means of a series connection of levers.

8. The measuring system according to claim 1, wherein the slider is held by means of guide springs.

9. The measuring system according to claim 1, wherein the electromechanical signal converter is based on a capacitance change.

10. The measuring system according to claim 1, wherein the force generator is a spring.

11. The measuring system according to claim 1, wherein the slider is a rigid mechanical element.

12. The measuring system according to claim 1, comprising a computer which is connected to the electrostatic actuator and/or the electrostatic anti-spring and/or the electromechanical signal converter and is configured to perform the offset compensation and/or the sensitivity adjustment.

13. A method for adjusting the sensitivity and/or for adjusting the measuring range of a micromechanical measuring system, comprising:
converting a physical signal into a displacement of an energy converter by means of the energy converter,
converting the displacement from the energy converter into a force on a movably mounted slider by means of a force generator, and
converting the displacement of the slider into an electrical signal by means of an electromechanical signal converter,
wherein the sensitivity of the measuring system is adjusted via a control voltage of an electrostatic anti-spring, which is connected to the slider and/or the force generator.

14. The method according of claim 13, further comprising:
measuring using the micromechanical measuring system,
performing out offset compensation,
increase sensitivity, and
repeating measurement using the measuring system.

15. Use of the micromechanical measuring system according to claim 1 in a strain sensor or acceleration sensor or temperature sensor.
